(19) United States
(12) Patent Application Publication
(10) Pub. No.: US 2017/0373125 A1
(43) Pub. Date: Dec. 28, 2017

(54) FLEXIBLE DISPLAY DEVICE AND METHOD OF MANUFACTURING THE SAME

(71) Applicant: Samsung Display Co., Ltd., Yongin-si, (KR)

(72) Inventors: Kikyung Youk, Yongin-si (KR); Seungchan Lee, Yongin-si (KR); Jeehun Lim, Yongin-si (KR); Wonjoon Choi, Yongin-si (KR); Jongdeok Park, Yongin-si (KR); Byungwook Ahn, Yongin-si (KR); Sukwon Jung, Yongin-si (KR); Jeongho Hwang, Yongin-si (KR)

(21) Appl. No.: 15/632,058

(22) Filed: Jun. 23, 2017

(30) Foreign Application Priority Data
Jun. 23, 2016 (KR) 10-2016-0078620

(51) Int. Cl. H01L 27/32; H01L 51/00; H01L 51/52; H01L 51/56

(52) U.S. Cl. CPC H01L 27/3262; H01L 51/56; H01L 51/0097; H01L 51/5253

(57) ABSTRACT

A flexible display device includes: a panel portion including a display area and a pad area; a window disposed over the panel; an adhesive layer disposed between the window and the panel portion; and a protection film disposed between the pad area and the adhesive layer.

### CROSS-REFERENCE TO RELATED APPLICATION

This application claims the benefit of Korean Patent Application No. 10-2016-0078620, filed on Jun. 23, 2016, in the Korean Intellectual Property Office, the disclosure of which is incorporated herein in its entirety by reference.

### BACKGROUND

### 1. Field

One or more embodiments relate to a flexible display device and a method of manufacturing the same.

### 2. Description of the Related Art

With the development of information technology, the market of display devices which connects users with information has expanded. Accordingly, the use of display devices such as liquid crystal displays (LCDs), organic light-emitting diode (OLED) displays, electrophoretic displays (EPDs), and plasma display panels (PDPs) displays increases.

Recently, flexible display panels that may be bent or unfolded in various directions as well as flat display panels have been in demand.

However, in the case of a flexible display panel, a driver chip for a display panel is mounted in a chip on film (COF) manner, and when the COF needs to be detached from the flexible display panel, the COF and the flexible display panel are damaged.

### SUMMARY

One or more embodiments include a flexible display device for performing a rework process without damaging a COF circuit and a panel, and a method of manufacturing the flexible display device.

Additional aspects will be set forth in part in the description which follows and, in part, will be apparent from the description, or may be learned by practice of the presented embodiments.

According to one or more embodiments, a flexible display device includes: a panel portion including a display area and a pad area; a window disposed over the panel; an adhesive layer disposed between the window and the panel portion; and a protection film disposed between the pad area and the adhesive layer.

The flexible display device may further include a flexible wiring board disposed over at least a portion of the pad area between the panel portion and the adhesive layer.

The flexible wiring board may include a chip on film (COF).

The flexible wiring board may include a flexible printed circuit board (FPCB), and the protection film may be disposed between the pad area and the adhesive layer in which the FPCB is not disposed.

The protection film may include a carbon compound in which a monomer having at least two carbon elements is polymerized or polymers including a benzene ring, fluorine, and chlorine.

The adhesive layer may have greater adhesion strength than the protection film.

The adhesion strength of the protection film may be lower than 100 gf/in².

The adhesion strength of the protection film may change according to certain conditions.

The protection film may have decreasing adhesion strength or no adhesion strength under the certain conditions.

The protection film may have decreasing adhesion strength or no adhesion strength at a low temperature.

The protection film may have decreasing adhesion strength or no adhesion strength under irradiation of short-wavelength light.

The protection film may have decreasing adhesion strength or no adhesion strength in a non-polar solvent.

The protection film may have a greater thickness than the adhesive layer.

The flexible display device may further include a polarization plate between the display area and the adhesive layer, an upper surface of the polarization plate and an upper surface of the protection film have a same height.

The display area may include: a substrate; a thin film transistor (TFT) above the substrate; and an organic light emitting device (OLED) above the substrate.

According to one or more embodiments, a method of manufacturing a flexible display device, includes: preparing a panel portion comprising a display area and a pad area; disposing a flexible wiring board over at least a portion of the pad area; disposing an adhesive layer over an upper portion of the panel portion; and disposing a window over the upper portion of the panel portion by using the adhesive layer. In the disposing of the flexible wiring board, the flexible wiring board is disposed over the at least a portion of the pad area by using a protection film which is disposed between the pad area and the adhesive layer.

The flexible wiring board may include a COF.

The protection film may be disposed between the pad area and the adhesive layer in which a flexible printed circuit (FPCB) is not disposed.

The method may further include disposing a polarization plate between the panel portion and the window before the window is disposed over the upper portion of the panel portion.

The adhesive layer may have greater adhesion strength than the protection film.

The adhesion strength of the protection film may be lower than 100 gf/in².

The protection film may have decreasing adhesion strength or no adhesion strength under certain conditions.

The method may further include performing a rework process of detaching the flexible wiring board before the disposing the window. In the performing of the rework process, the protection film and the adhesive layer may be removed from the panel portion without damaging the flexible wiring board and the pad area.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a flexible display device according to an embodiment;

FIG. 2 is a cross-sectional view taken along a line II-II′ of FIG. 1;

FIG. 3 is a schematic perspective view of a flexible display device according to an embodiment;

FIG. 4 is an exploded view of the flexible display device of FIG. 3;

FIG. 5A is a cross-sectional view taken along a line V-V of FIG. 3;

FIG. 5B is a schematic cross-sectional view of a flexible display device according to another embodiment;

FIG. 6A is a cross-sectional view showing a state in which a chip on film (COF) is attached when a method of manufacturing a flexible display device, according to an embodiment, is performed; and

FIG. 6B is a cross-sectional view showing a process of detaching a COF during a rework process of a method of manufacturing a flexible display device, according to an embodiment.

### DETAILED DESCRIPTION

As the present disclosure allows for various changes and numerous embodiments, particular embodiments will be illustrated in the drawings and described in detail in the written description. The attached drawings for illustrating preferred embodiments of the present disclosure are referred to in order to gain a sufficient understanding of the present disclosure, the merits thereof, and the objectives accomplished by the implementation of the present disclosure. The present disclosure may, however, be embodied in many different forms and should not be construed as being limited to the embodiments set forth herein.

The present disclosure will now be described more fully with reference to the accompanying drawings, in which exemplary embodiments of the present disclosure are shown. Like reference numerals in the drawings denote like elements, and thus their description will be omitted.

It will be understood that although the terms “first”, “second”, etc. may be used herein to describe various components, these components should not be limited by these terms.

As used herein, the singular forms “a”, “an”, and “the” are intended to include the plural forms as well, unless the context clearly indicates otherwise. It will be further understood that the terms “comprises” and/or “comprising” used herein specify the presence of stated features or components, but do not preclude the presence or addition of one or more other features or components.

It will be understood that when a layer, region, or component is referred to as being “formed on” another layer, region, or component, it can be directly or indirectly formed on the other layer, region, or component. That is, for example, intervening layers, regions, or components may be present.

Sizes of components in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

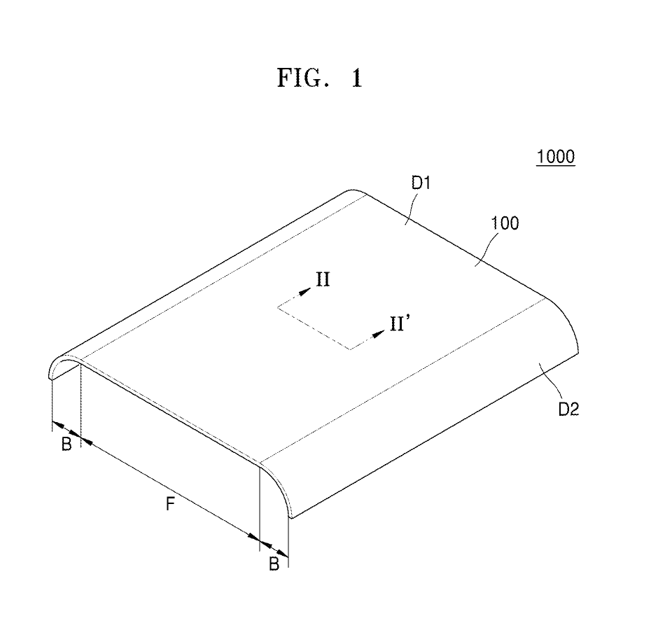

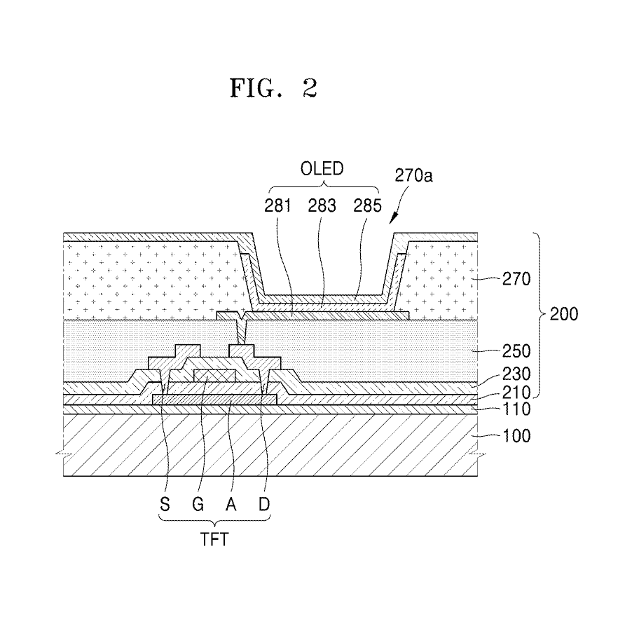

FIG. 1 is a perspective view of a flexible display device 1000 according to an embodiment, and FIG. 2 is a cross-sectional view taken along a line of FIG. 1.

Referring to FIGS. 1 and 2, the flexible display device 1000 may include a substrate 100 and a display unit 200 above the substrate 100, and the display unit 200 may include a first display area D1 and a second display area D2.

The substrate 100 may include a flexible plastic material. For example, the substrate 100 may include polyethersulphone (PES), polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose triacetate (TAC), cellulose acetate propionate (CAP), or the like.

When the flexible display device 1000 is of a bottom-emission type in which an image is produced toward the substrate 100, the substrate 100 includes a transparent material. However, when the flexible display device 1000 is of a top-emission type in which an image is produced toward the display unit 200, the substrate 100 does not have to include a transparent material. In this case, the substrate 100 may include a flexible opaque metallic material. When the substrate 100 includes a metallic material, the substrate 100 may include at least one selected from the group consisting of iron (Fe), chromium (Cu), manganese (Mn), nickel (Ni), titanium (Ti), molybdenum (Mo), stainless steel (SUS), an Invar alloy, an Inconel alloy, and a Kovar alloy. Also, the substrate 100 may include metal foil.

The substrate 100 may include a flat portion F and at least one bent portion B. The bent portion B extends from the flat portion F. FIG. 1 shows the substrate 100 including the flat portion F and a pair of bent portions B disposed on both sides of the flat portion F. The bent portions B may have the same shape or different shapes. Also, the bent portions B may have a uniform radius of curvature or radii of curvature which is changed in the bent portion B. However, the present disclosure is not limited thereto. The bent portion B may be, for example, formed on any one or both sides of the flat portion F or may be formed inside the flat portion F.

As shown in FIG. 2, the display unit 200 is formed above the substrate 100 and produces images. The display unit 200 may include, for example, a thin film transistor (TFT) and an organic light-emitting diode (OLED). However, the present disclosure is not limited thereto, and the display unit 200 may include various display devices.

Hereinafter, the display unit 200 will be described in more detail with reference to FIG. 2.

A buffer layer 110 may be formed above the substrate 100. The buffer layer 110 may prevent impurity ions from diffusing into the display unit 200, prevent external moisture or oxygen from penetrating the display unit 200, and function as a barrier layer and/or a planarization layer for flattening a surface of the substrate 100. The buffer layer 110 may include, for example, an inorganic material such as silicon oxide (SiOx), silicon nitride (SiNx), silicon oxynitride (SiON), aluminum oxide (Al₂O₃), aluminum nitride (AlN), titanium oxide (TiO₂), or titanium nitride (TiN), or an organic material such as polyimide, polyester, or acryl. The buffer layer 110 may include a laminated layer including a stack of the aforementioned materials.

The TFT may be formed above the substrate 100. The TFT may include a semiconductor layer A, a gate electrode G, a source electrode S, and a drain electrode D. FIG. 2 shows the TFT of a top gate type which sequentially includes the semiconductor layer A, the gate electrode G, the source electrode S, and the drain electrode D in this stated order. However, the present disclosure is not limited thereto. The TFT may be of various types such as a bottom gate type TFT.

The semiconductor layer A may include an inorganic semiconductor such as silicon or an organic semiconductor. Also, the semiconductor layer A may have a source area, a drain area, and a channel area disposed therebetween. For example, when the semiconductor layer A includes amorphous silicon, an amorphous silicon layer that is formed above the entire substrate 100 is crystallized into a polycrystalline silicon layer, and the polycrystalline silicon layer is patterned. Then, the semiconductor layer including the source area, the drain area, and the channel area disposed therebetween may be formed by doping the source area and the drain area with impurities.

After the semiconductor layer A is formed, a gate insulating layer 210 is formed on the semiconductor layer A above the entire substrate 100. The gate insulating layer 210 may be a single layer or layers including an inorganic material such as SiOx or SiNx. The gate insulating layer 210 insulates the semiconductor layer A from the gate electrode G disposed above the semiconductor layer A.

The gate electrode G is formed above a certain portion of the gate insulating layer 210. The gate electrode G is connected to a gate line (not shown) that applies an on/off signal of the TFT. The gate electrode G may include a metallic material selected from the group consisting of Mo, aluminum (Al), platinum (Pt), palladium (Pd), silver (Ag), magnesium (Mg), gold (Au), nickel (Ni), neodymium (Nd), iridium (Ir), Cr, lithium (Li), calcium (Ca), Ti, tungsten (W), and copper (Cu). However, the material of the gate electrode G is not limited thereto and may vary according to design conditions of the TFT.

After the gate electrode G is formed, an interlayer insulating layer 230 may be formed above the entire substrate 100 in order to insulate the source electrode S and the drain electrode D from the gate electrode G.

The interlayer insulating layer 230 may include an inorganic material. For example, the interlayer insulating layer 230 may include a metal oxide or a metal nitride and, particularly, SiOx, SiNx, SiON, Al₂O₃, TiO₂, tantalum oxide (Ta₂O₅), hafnium oxide (HfO₂), or zinc oxide (ZrO₂).

The interlayer insulating layer 230 may be a single layer or multi-layers including an inorganic material such as SiOx and/or SiNx. In some embodiments, the interlayer insulating layer 230 may have a double structure including SiOx/SiNy or SiNx/SiOy.

The source electrode S and the drain electrode D are formed above the interlayer insulating layer 230. In detail, the interlayer insulating layer 230 and the gate insulating layer 210 expose the source area and the drain area of the semiconductor layer A, and the source electrode S and the drain electrode D contact the exposed source area and drain area of the semiconductor layer A.

The source electrode S and the drain electrode D may each be a single layer or multi-layers including at least one of Al, Pt, Pd, Ag, Mg, Au, Ni, Nd, Ir, Cr, Li, Ca, Mo, Ti, W, and Cu.

The TFT is electrically connected to the OLED and transmits thereto a signal for operating the OLED. The TFT may be covered and protected by a planarization layer 250.

The planarization layer 250 may be an inorganic insulating layer and/or an organic insulating layer. The inorganic insulating layer may include SiO₂, SiNx, SiON, Al₂O₃, TiO₂, Ta₂O₅, HfO₂, ZrO₂, BST, PZT, or the like, and the organic insulating layer may include polymethyl methacrylate (PMMA, PS), polymer derivatives having a phenol-based group, acryl-based polymers, imide-based polymers, aryl ether-based polymers, amide-based polymers, fluorine-based polymers, p-xylene-based polymers, vinyl alcohol-based polymers, and combination thereof. Also, the planarization layer 250 may be a laminated layer in which the inorganic insulating layer and the organic insulating layer are stacked.

The OLED may be formed above the planarization layer 250. The OLED may include a first electrode 281, an intermediate layer 283 including an organic emission layer, and a second electrode 285. Holes and electrons injected from the first electrode 281 and the second electrode 285 of the OLED combine with each other in the intermediate layer 283 which is an inorganic layer or an organic layer, and thus light may be emitted.

The first electrode 281 is formed above the planarization layer 250 and is electrically connected to the drain electrode D through a contact hole in the planarization layer 250. However, the present disclosure is not limited thereto. The first electrode 281 may be electrically connected to the source electrode S and may receive a signal for operating the OLED therethrough.

The first electrode 281 may be a reflective electrode and may include a reflective layer including Ag, Mg, Al, Pt, Pd, Au, Ni, Nd, Ir, Cr, or a combination thereof and a transparent or translucent electrode layer formed above the reflective layer. The transparent or translucent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO).

The intermediate layer 283 may include the organic emission layer or the inorganic emission layer. As a selective example, the intermediate layer 283 may include the organic emission layer and may further include at least one of a hole injection layer (HIL), a hole transport layer (HTL), an electron transport layer (ETL), and an electron injection layer (EIL). However, the present embodiment is not limited thereto. The intermediate layer 283 may include the organic emission layer and may further include various functional layers.

The second electrode 285 may be formed above the intermediate layer 283. The second electrode 285 forms an electric field with the first electrode 281, and thus the intermediate layer 283 emits light. The first electrode 281 may be patterned in a pixel unit, and a common voltage may be applied to all pixels of the second electrode 285.

The second electrode 285 facing the first electrode 281 may be a transparent or translucent electrode and may include a metallic thin film having a small work function and including Li, Ca, LiF/Ca, LiF/Al, Al, Ag, Mg, and a combination thereof. An auxiliary electrode layer or a bus electrode may be further formed above the metallic thin film, the auxiliary electrode layer or the bus electrode including a material for forming a transparent electrode such as ITO, IZO, ZnO, or In₂O₃.

Therefore, the second electrode 285 may pass the light emitted from the organic emission layer (not shown) of the intermediate layer 283. That is, the light emitted from the organic emission layer is emitted toward the second electrode 285 directly or after reflected from the first electrode 281.

However, a type of the display unit 200 is not limited to a top emission type. The display unit 200 may be of a bottom emission type in which the light emitted from the organic emission layer (not shown) is emitted toward the substrate 100. In this case, the first electrode 281 may be a transparent or translucent electrode, and the second electrode 285 may be a reflective electrode. Also, the display unit 200 may be of a dual emission type in which light is emitted in two directions, that is, towards a top surface and a rear surface of the display unit 200.

As a selective example, the first electrode 281 may be patterned, for example, in a pixel unit. The display unit 200 may further include a pixel defining layer 270 above the first electrode 281. The pixel defining layer 270 may include an opening 270a exposing the first electrode 281. The intermediate layer 283 may be formed at a location corresponding to the opening 270a and may be electrically connected to the first electrode 281. The pixel defining layer 270 may include at least one organic insulating layer selected from the group consisting of polyimide, polyamide, acryl resin, benzocyclobutene (BCB), and phenol resin and may be formed through spin coating, etc.

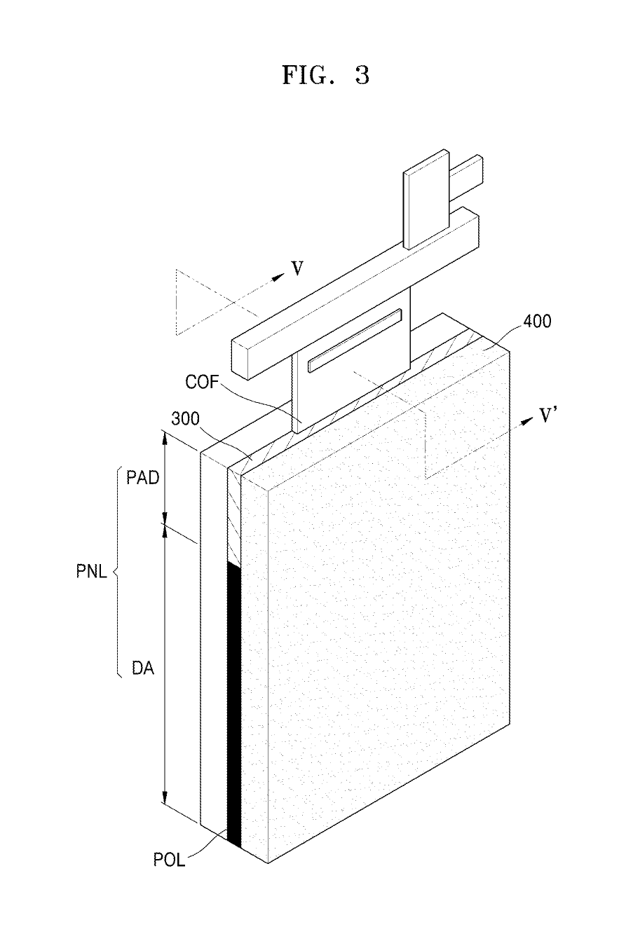

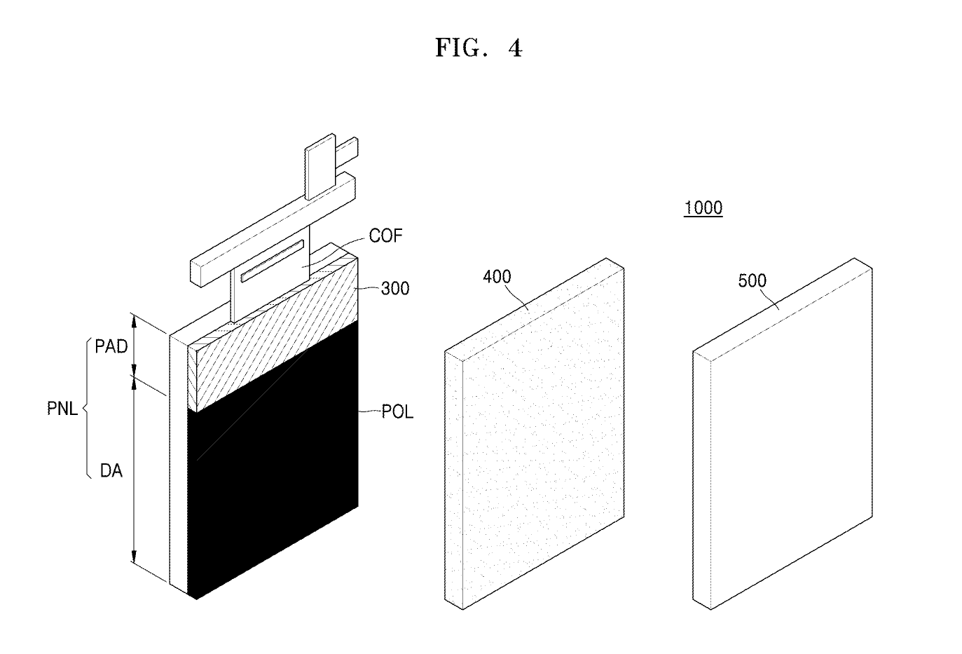

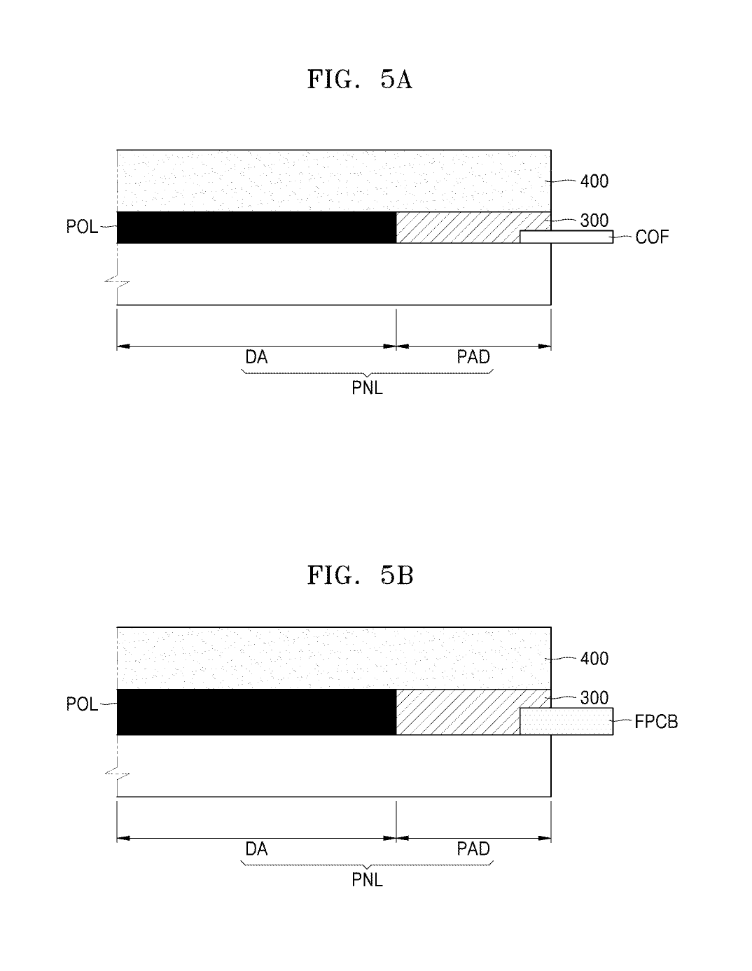

FIG. 3 is a schematic perspective view showing a flexible display device according to an embodiment. FIG. 4 is an exploded view of the flexible display device of FIG. 3. FIG. 5A is a cross-sectional view taken along a line V-V of FIG. 3.

The flexible display device may include a panel portion PNL, a flexible wiring board connected to a pad area PAD located on a non-display area of the panel portion PNL, and a protection film 300 that attaches the flexible wiring board to the pad area PAD. The flexible wiring board may be a wiring board, for example, a flexible printed circuit board (FPCB), a chip on film (COF) or a chip on flexible printed circuit, which includes various wiring circuits. However, FIG. 3 shows a COF as the flexible wiring board. Hereinafter, a flexible display device including a COF as a flexible wiring board will be described with reference to FIGS. 3 to 5A.

The panel portion PNL may include the substrate 100 and the display unit 200 disposed above the substrate 100, and detailed descriptions of the substrate 100 and the display unit 200 are provided above with reference to FIGS. 1 and 2 and thus are omitted.

The COF denotes all types of circuit devices such as drive ICs for driving a flexible display panel including a switching device and emission materials and may be referred to as a flexible printed circuit (FPC), a COF circuit, a chip on flexible printed circuit.

The COF is manufactured separately from the panel portion PNL and mounted on part of the non-display area of the panel portion PNL, for example, at least a portion of the pad area PAD of the panel portion PNL, as shown in FIG. 3.

In the COF, multiple circuit devices and wires or signal lines may be formed, and end portions of the wires or the signal lines may be electrically connected to pads in the pad area PAD of the panel portion PNL.

The flexible display device of the present embodiment includes the OLED display device, an electrophoretic display device, etc., and a COF connected to one side of the panel portion PNL.

As described above, the display unit 200 of the panel portion PNL formed above the substrate 100 includes gate lines and data lines, and a cell or pixel area is defined in each area where the data lines cross each other. In each pixel area, a TFT (refer to FIG. 2) for switching electrical signals is formed.

Therefore, the panel portion PNL includes wire lines (not shown), and a pad (not shown) to be connected to a driving circuit such as a COF may be formed on an end of the wire line.

Driving units such as a gate driving unit and a data driving unit are necessary to drive the panel portion PNL by respectively transmitting a gate signal and a data signal to the gate line and the data line. The gate driving unit may be formed in a gate-in-panel (GIP) manner in which the gate driving unit is formed as a circuit device in the panel portion PNL directly. Alternatively, the gate driving unit may be formed as a separate circuit device and mounted on the panel portion PNL.

In particular, the data driving unit is embodied as an integrated circuit device that is referred to as a drive IC and may be connected to a bonding pads of the flexible display panel 1000 in a tape automated bonding (TAB) manner or a chip on glass (COG) manner.

The COF may be attached to the pad area PAD of the panel portion PNL by using the protection film 300.

The flexible display device 1000 may include the protection film 300 at a location corresponding to a location where the COF is mounted. The COF may be mounted on a center of the pad area.

As a selective example, the protection film 300 includes a material having a lower adhesion strength than that of an adhesive layer which will be described later and may be used to attach the COF to the panel portion PNL. Then, when a rework process of detaching a COF circuit is performed due to misalignment of the COF, etc., the COF may be detached from the pad area PAD without causing damage by the protection film 300.

As a selective example, the protection film 300 may include an adhesive, for example, pressure-sensitive adhesive (PSA), a film including PET, or the like.

As another selective example, the protection film 300 may include at least one of a carbon compound in which a monomer including at least two carbon elements is polymerized and polymers including a benzene ring, fluorine, and chlorine.

As a selective example, the protection film 300 may have an adhesion strength lower than 100 gf/in². That is, the protection film 300 may have much lower adhesion strength than an adhesive layer 400 used to adhere a window to the panel portion PNL.

As another selective example, the protection film 300 may include a material having adhesion that changes according to certain conditions.

The protection film 300 may include a material having adhesion strength that decreases at a low temperature. Thus, as temperature conditions are adjusted, the protection film 300 may have decreased adhesion strength or no adhesion strength.

That is, if a temperature is lowered when the COF needs to be detached, the adhesion strength of the protection film 300 decreases, and thus the COF may be easily detached without damaging the COF and the pad area PAD.

The protection film 300 may include a material having adhesion strength that decreases under irradiation of short wavelength light. Thus, as wavelength conditions of the light irradiated are adjusted, the protection film 300 may have decreased adhesion strength or no adhesion strength.

That is, if the protection film 300 is irradiated by a short wavelength light when the COF needs to be detached, the adhesion of the protection film 300 decreases such that the COF may be easily detached without damage of the COF and the pad area PAD.

The protection film 300 may include a material having adhesion strength decreasing in a non-polar solvent. Thus, as polar/non-polar conditions are adjusted, the protection film 300 may have decreased adhesion strength or no adhesion strength.

That is, if the protection film 300 is under non-polar solvent conditions when the COF needs to be detached, the adhesion strength of the protection film 300 decreases such that the COF may be easily detached without damage of the COF and the pad area PAD.

The flexible display device 1000 according to the present embodiment may further include a window 500 disposed above the panel portion PNL.

The window 500 may be disposed on a side where light is emitted from the panel portion PNL and may protect the panel portion PNL from the outside.

As a selective example, the window 500 may include a glass material.

The window 500 may be attached to the panel portion PNL by the adhesive layer 400 having greater adhesion strength than the protection film 300.

The adhesive layer 400 may include a material having greater adhesion strength than the protection film 300. For example, the adhesive layer 400 may include at least one of polyacrylate, a polymer including polyacrylate and silicon, and rubber-like natural or synthetic carbon compound.

As being attached to the panel portion PNL by the adhesion layer 400 having greater adhesion strength than the protection film 300, the window 500 may protect the panel portion PNL without being detached.

In a conventional display device, when no protection film 300 is disposed between the panel portion PNL and the adhesive layer 400, the COF is also attached to the panel portion PNL by the adhesion layer 400 having greater adhesion strength than the protection layer 300. Accordingly, when the COF needs to be attached and then detached, the COF as well as the pad area PAD of the panel portion PNL are damaged by the adhesive layer 400 having great adhesion strength during the rework process of detaching the COF.

Therefore, since a COF and a pad area PAD need to be newly prepared, the manufacture of the display device requires a lot of time and costs.

On the contrary, in the case of the flexible display panel according to the present embodiment, the window 500 is attached to an upper portion of the panel portion PNL by the adhesive layer 400 having great adhesion strength, and the COF is attached by the protection film 300 having low adhesion strength and interposed between the pad area PAD of the panel portion PNL and the adhesive layer 400. Thus, although the rework process is performed, the COF may be easily detached without damage of the COF and the pad area PAD.

As a selective example, as shown in FIGS. 3 and 4, a polarization plate POL may be further formed on a surface of the panel portion PNL of the flexible display device 1000. The polarization plate POL may be formed between the panel portion PNL and the window 500.

As a selective example, the polarization plate POL is a linear polarizer which passes linear polarization in an arbitrary first direction and reflects linear polarization in a second direction perpendicular to the first direction. Since the polarization plate POL is of a film type and has a thickness of several tens of μm, the flexible display device 1000 may be of a thin film type and may have increased brightness because the polarization plate POL has high transmittance.

A shape and characteristics of the polarization plate POL are not limited thereto and may vary. Thus, brightness of the flexible display device 1000 may be improved.

FIG. 5B is a schematic cross-sectional view of a flexible display device according to another embodiment. Like reference numerals in FIGS. 5A and 5B denote like elements, and descriptions thereof will be omitted for convenience.

As a selective example, the flexible wiring board attached to at least a portion of the pad area PAD may be an FPCB as shown in FIG. 5B.

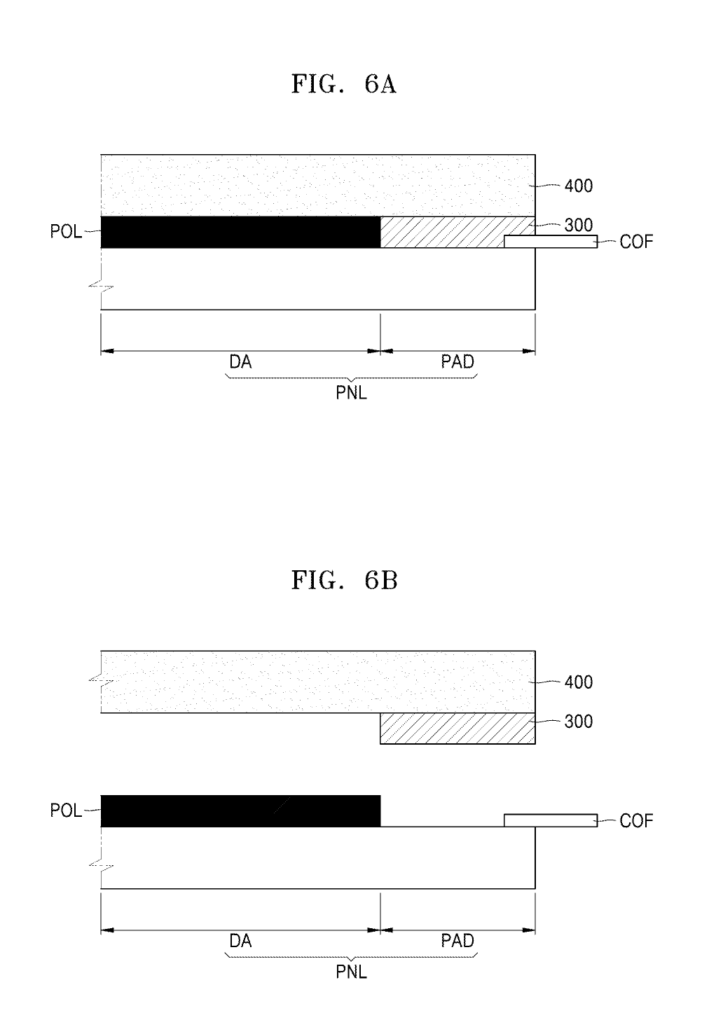

FIG. 6A is a cross-sectional view showing a state in which the COF is attached when the method of FIG. 3 of manufacturing the flexible display device 1000 is performed, and FIG. 6B is a cross-sectional view showing a process of detaching the COF during a rework process of the method of FIG. 3 of manufacturing the flexible display device 1000.

Like reference numerals in FIGS. 1 to 6B denote like elements, and detailed descriptions thereof will be omitted.

As shown in FIG. 6A, the panel portion PNL including the display area DA and the pad area PAD may be prepared, and the COF may be mounted on the pad area PAD.

The display area DA may include the substrate 100 and the display unit 200 disposed above the substrate 100.

As a selective example, as shown in FIG. 2, the display unit 200 may include the TFT and the OLED.

The COF may be attached to the pad area PAD, and the protection film 300 used to attach the COF may be formed at a location corresponding to the pad area PAD.

That is, the COF may be attached to the pad area PAD by the protection 300.

The protection film 300 may include a material having low adhesion strength. For example, the protection film 300 may include at least one of a carbon compound in which a monomer including at least two carbon elements is polymerized, and polymers including a benzene ring, fluorine, and chlorine.

As a selective example, the protection film 300 may have adhesion strength lower than 100 gf/in².

As another selective example, the protection film 300 may include a material having adhesion strength that changes according to certain conditions. In particular, the protection film 300 may include a material having decreased adhesion strength or no adhesion strength according to certain conditions.

Also, similar to the COF, the polarization plate POL may be attached to the upper portion of the panel portion PNL.

As a selective example, the polarization plate POL may be attached to the panel portion PNL by a separate adhesive layer (not shown). As shown in FIG. 6A, the polarization plate POL may be of a film type and have a thickness of several tens of μm such that the flexible display device 1000 may be of a thin film type and may have high brightness because the polarization plate POL has high transmittance. The upper surface of the polarization plate POL and the upper surface of the protection film 300 may have a same height.

The adhesive layer 400 may be formed above the panel portion PNL on which the COF is attached to the pad area PAD by the protection film 300.

The adhesive layer 400 may include a material having greater adhesion strength than the protection film 300. For example, the adhesive layer 400 may include at least one of polyacrylate, a polymer including polyacrylate and silicon, and rubber-like natural or synthetic carbon compound.

Referring to FIG. 6B, the rework process of detaching the COF from the panel portion PNL may be performed when the COF is misaligned or the COF has other problems.

When the COF needs to be detached due to its misalignment, if it is difficult to detach the COF, the COF and the panel portion PNL may not be used again. Thus, a lot of time and costs may be required.

In a conventional case, the COF is attached to the panel portion PNL by using the adhesive layer 400 having great adhesion strength and used to attach the window 500 (refer to FIG. 5A), and accordingly, when the COF is detached, the COF and the pad area PAD of the panel portion PNL are damaged.

In the method of manufacturing the flexible display device according to the present embodiment, the COF is attached to the pad area PAD by the protection film 300 having low adhesion strength. Then, the window 500 is attached to the protection film 300, the COF may be easily detached during the rework process.

That is, according to the method of manufacturing the flexible display device, according to the present embodiment, as shown in FIG. 6B, the adhesive layer 400 and the protection film 300 may be removed without damaging the pad area PAD of the panel portion PNL and the COF by using the protection film 300 having low adhesion strength.

According to the one or more embodiments, a COF circuit may be removed from a panel without damaging the COF circuit and a pad area of the panel while a rework process is performed.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope as defined by the following claims.

What is claimed is:

1. A flexible display device comprising:
a panel portion comprising a display area and a pad area;
a protection film disposed over the pad area; and
an adhesive layer disposed over the protection film and the display area.

2. The flexible display device of claim 1, further comprising a flexible wiring board disposed over at least a portion of the pad area between the panel portion and the adhesive layer.

3. The flexible display device of claim 2, wherein the flexible wiring board comprises a chip on film (COF).

4. The flexible display device of claim 2, wherein the flexible wiring board comprises a flexible printed circuit board (FPCB), and
the protection film is disposed between the pad area and the adhesive layer in which the FPCB is not disposed.

5. The flexible display device of claim 1, wherein the protection film comprises a carbon compound in which a monomer having at least two carbon elements is polymerized or polymers comprising a benzene ring, fluorine, and chlorine.

6. The flexible display device of claim 1, wherein the adhesive layer has greater adhesion strength than the protection film.

7. The flexible display device of claim 1, wherein the adhesion strength of the protection film is lower than 100 gf/in².

8. The flexible display device of claim 1, wherein the adhesion strength of the protection film changes according to certain conditions.

9. The flexible display device of claim 8, wherein the protection film has decreasing adhesion strength or no adhesion strength under the certain conditions.

10. The flexible display device of claim 9, wherein the protection film has decreasing adhesion strength or no adhesion strength at a low temperature.

11. The flexible display device of claim 9, wherein the protection film has decreasing adhesion strength or no adhesion strength under irradiation of short-wavelength light.

12. The flexible display device of claim 9, wherein the protection film has decreasing adhesion strength or no adhesion strength in a non-polar solvent.

13. The flexible display device of claim 1, wherein the protection film has a greater thickness than the adhesive layer.

14. The flexible display device of claim 1, further comprising a polarization plate between the display area and the adhesive layer, an upper surface of the polarization plate and an upper surface of the protection film have a same height.

15. The flexible display device of claim 1, wherein the display area comprises:
a substrate;
a thin film transistor (TFT) above the substrate; and
an organic light emitting device (OLED) above the substrate.

16. The flexible display device of claim 1, further comprising a window disposed over the panel portion.

17. A method of manufacturing a flexible display device, the method comprising:
preparing a panel portion comprising a display area and a pad area;
disposing a flexible wiring board over at least a portion of the pad area; and
disposing an adhesive layer over an upper portion of the panel portion,
wherein, in the disposing of the flexible wiring board, the flexible wiring board is disposed over the at least a portion of the pad area by using a protection film which is disposed between the pad area and the adhesive layer.

18. The method of claim 17, wherein the flexible wiring board comprises a chip on film (COF).

19. The method of claim 18, wherein the protection film is disposed between the pad area and the adhesive layer in which a flexible printed circuit (FPCB) is not disposed.

20. The method of claim 17, further comprising:
disposing a window over the upper portion of the panel portion by using the adhesive layer; and
disposing a polarization plate between the panel portion and the window before the window is disposed over the upper portion of the panel portion.

21. The method of claim 17, wherein the adhesive layer has greater adhesion than the protection film.

22. The method of claim 21, wherein the adhesion strength of the protection film is lower than 100 gf/in².

23. The method of claim 17, wherein the protection film has decreasing adhesion strength or no adhesion strength under certain conditions.

24. The method of claim 17, further comprising:
disposing a window over the upper portion of the panel portion by using the adhesive layer; and
performing a rework process of detaching the flexible wiring board before the disposing the window,
wherein, in the performing of the rework process, the protection film and the adhesive layer are removed from the panel portion without damaging the flexible wiring board and the pad area.
